(19) United States
(12) Patent Application Publication
(10) Pub. No.: US 2019/0129530 A1
(43) Pub. Date: May 2, 2019

(54) UNDER DISPLAY BIOMETRIC SENSOR

(71) Applicant: Synaptics Incorporated, San Jose, CA (US)

(72) Inventor: Guozhong Shen, San Jose, CA (US)

(21) Appl. No.: 16/157,935

(22) Filed: Oct. 11, 2018

Related U.S. Application Data
(60) Provisional application No. 62/579,042, filed on Oct. 30, 2017.

(51) Int. Cl. G06F 3/042; G06K 9/00; H01L 25/16; H01L 27/12; H01L 27/146; H04N 5/225

(52) U.S. Cl. CPC G06F 3/042; G06K 9/0008; G06K 9/00087; H04N 5/2253; H01L 27/1214; H01L 27/14621; H01L 25/167

(57) ABSTRACT

An under display imaging device for imaging a biometric input object is provided. The under display imaging device includes a sensor comprising an array of sensing elements, the sensor being configured to be mounted below a display.

### CROSS REFERENCE TO RELATED APPLICATIONS

This application claims the benefit of U.S. Provisional Application Ser. No. 62/579,042, entitled “Under Display Biometric Sensor with Noise Mitigation,” filed Oct. 30, 2017, the contents of which are expressly incorporated by reference.

### FIELD

This disclosure generally relates to sensors, and more particularly to a sensor which may be integrated in a display stack up.

### BACKGROUND

Object imaging is useful in a variety of applications. By way of example, biometric recognition systems image biometric objects for authenticating and/or verifying users of devices incorporating the recognition systems. Biometric imaging provides a reliable, non-intrusive way to verify individual identity for recognition purposes. Various types of sensors may be used for biometric imaging.

Fingerprints are an example of a biometric object that may be imaged. Fingerprints, like various other biometric characteristics, are based on distinctive personal characteristics and provide a reliable mechanism to recognize an individual. Thus, fingerprint sensors have many potential applications. For example, fingerprint sensors may be used to provide access control in stationary applications, such as security checkpoints. Fingerprint sensors may also be used to provide access control in mobile devices, such as cell phones, wearable smart devices (e.g., smart watches and activity trackers), tablet computers, personal data assistants (PDAs), navigation devices, automotive devices, touchpads, and portable gaming devices. Accordingly, some applications, in particular applications related to mobile devices, may require recognition systems that are both small in size and highly reliable.

Fingerprint sensors in most mobile devices are capacitive sensors having a capacitive sensing array configured to sense ridge and valley features of a fingerprint. Typically, these fingerprint sensors either detect absolute capacitance (sometimes known as “self-capacitance”) or trans-capacitance (sometimes known as “mutual capacitance”). In either case, capacitance at each sensing element in the array varies depending on whether a ridge or valley is present, and these variations are electrically detected to form an image of the fingerprint.

While capacitive fingerprint sensors provide certain advantages, most commercially available capacitive fingerprint sensors have difficulty sensing fine ridge and valley features through large distances, requiring the fingerprint to contact a sensing surface that is close to the sensing array. It remains a significant challenge for a capacitive sensor to detect fingerprints through thick layers, such as the thick cover glass (sometimes referred to herein as a “cover lens”) that protects the display of many smart phones and other mobile devices. To address this issue, a cutout is often formed in the cover glass in an area beside the display, and a discrete capacitive fingerprint sensor (often integrated with a button) is placed in the cutout area so that it can detect fingerprints without having to sense through the cover glass. The need for a cutout makes it difficult to form a flush surface on the face of device, detracting from the user experience, and complicating the manufacture. The existence of mechanical buttons also takes up valuable device real estate.

Optical sensors provide an alternative to capacitive sensors. Acoustic (e.g., ultrasound) sensors also provide an alternative to capacitive sensors. Such sensors may be integrated within the display of an electronic device. However, optical and acoustic sensors are susceptible to wideband and narrowband noise caused by, for the example, components of the display. The noise can interfere with imaging of an input object, such as a biometric input object. Additionally, optical sensors can add to device thickness thereby also taking up valuable real estate.

### SUMMARY

One embodiment provides an under display imaging device for imaging an input object. The imaging device includes an image sensor comprising an array of sensing elements, the image sensor being configured to be mounted below a display; and a noise shield layer disposed above and covering the array of sensing elements.

Another embodiment provides an under display optical imaging device for imaging an input object. The optical imaging devices includes an emissive display; an optical sensor comprising an array of optical sensing elements, the optical sensor being configured to be mounted below a display; and a noise shield layer disposed above and covering the array of optical sensing elements.

Another embodiment provides an electronic device for imaging an input object. The electronic device includes an emissive display. The emissive display includes a first display layer comprising an array of display elements and associated control circuitry; and a second display layer disposed below the first layer, the second layer including a noise shield. The noise shield includes a first conductive layer, wherein the first conductive layer is transparent; and a second conductive layer electrically connected to the first conductive layer, wherein the second conductive layer is opaque and wherein the second layer includes an array of gaps allowing light to pass therethrough.

Another embodiment provides a display for an electronic device. The display includes a display substrate with a light filter configured to only allow light falling within an acceptance angle to pass through the light filter; and a pixel layer having a plurality of display pixels and control circuitry disposed on the display substrate.

### BRIEF DESCRIPTION OF THE DRAWINGS

FIG. 1 is a block diagram of an example of a system that includes an image sensor and a processing system.

FIG. 2 illustrates an example of an image sensor according to an embodiment.

FIGS. 3A-3D illustrate examples of image sensors having sensing elements with noise mitigation shielding according to certain embodiments.

FIG. 4 illustrates an example of an optical thin film transistor (TFT) sensor with noise mitigation shielding according to an embodiment.

FIG. 5 illustrates a method for making an image sensor according to an embodiment.

FIG. 6 illustrates an example of an image sensor integrated in a display.

FIG. 7 illustrates a display substrate with embedded filter.

FIG. 8 illustrates a method of making an image sensor with a substrate embedded filter.

### DETAILED DESCRIPTION

The following detailed description is exemplary in nature and is not intended to limit the invention or the application and uses of the invention. Furthermore, there is no intention to be bound by any expressed or implied theory presented in the preceding technical field, background, summary, brief description of the drawings, or the following detailed description.

Turning to the drawings, and as described in greater detail herein, embodiments provide systems and methods to mitigate noise in an image sensor, also referred to as a sensor, such as an under display biometric sensor. The noise mitigation includes a shield layer interposed between the display and a sensor array. The sensor array may be a variety of types such as a thin film transistor (TFT) optical sensor, CMOS optical sensor, or ultrasonic sensor. The shield layer may include a conductive and optically transparent layer (transparent conductive material), such as an indium tin oxide (ITO) layer, and/or a conductive and optically opaque layer, such as a metal or metalized layer. The shield layer may also be a multi-layer shield, e.g., having both a transparent portion and metal portion. One or more layers may cover the entire sensor, while one or more other layers may cover selective portions of the sensor.

Also described herein are systems and methods of integrating a sensor, such as a biometric sensor within a display.

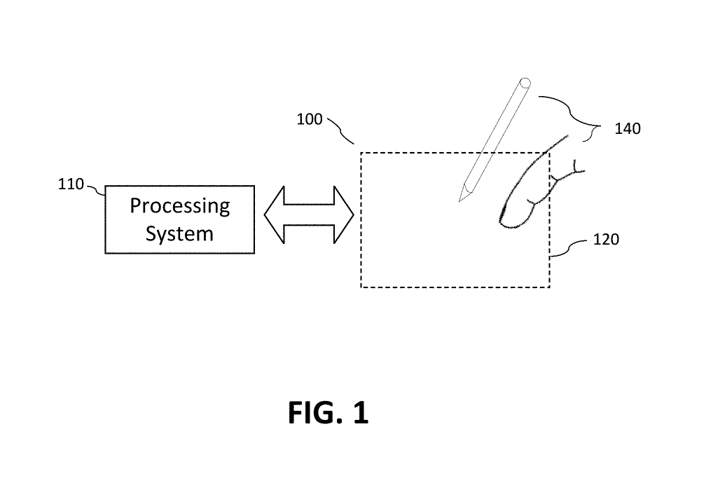

FIG. 1 is a block diagram of an exemplary sensing system having a sensor 100, in accordance with certain embodiments. The sensor 100 may be configured to provide input to an electronic system (also “electronic device”). Some non-limiting examples of electronic systems include personal computers of all sizes and shapes, such as desktop computers, laptop computers, netbook computers, tablets, e-book readers, personal digital assistants (PDAs), and wearable computers (such as smart watches and activity tracker devices). Additional example electronic systems include composite input devices, such as physical keyboards that include input device 100 and separate joysticks or key switches. Further example electronic systems include peripherals such as data input devices (including remote controls and mice), and data output devices (including display screens and printers). Other examples include remote terminals, kiosks, and video game machines (e.g., video game consoles, portable gaming devices, and the like). Other examples include communication devices (including cellular phones, such as smart phones), and media devices (including recorders, editors, and players such as televisions, set-top boxes, music players, digital photo frames, and digital cameras). Additionally, the electronic system could be a host or a slave to the input device.

The sensor 100 can be implemented as a physical part of the electronic system, or can be physically separate from the electronic system. The sensor 100 may be integrated as part of a display of an electronic device. As appropriate, the sensor 100 may communicate with parts of the electronic system using any one or more of the following: buses, networks, and other wired or wireless interconnections. Examples include I2C, SPI, PS/2, Universal Serial Bus (USB), Bluetooth®, RF, and IRDA.

The sensor 100 is configured to sense input provided by one or more input objects 140 in a sensing region 120. In one embodiment, the input object 140 is a finger, and the sensor 100 is implemented as a fingerprint sensor (also “fingerprint scanner”) configured to detect fingerprint features of the input object 140. In other embodiments, the sensor 100 may be implemented as vascular sensor (e.g., for finger vein recognition), hand geometry sensor, or a proximity sensor (such as a touch pad, touch screen, and or other devices). In other embodiments, the sensor may be used for heart rate detection by monitoring dynamic changes in reflectance of the image.

Sensing region 120 encompasses any space above, around, in, and/or near the sensor 100 in which the sensor 100 is able to detect input (e.g., user input provided by one or more input objects 140). The sizes, shapes, and locations of particular sensing regions may vary widely from embodiment to embodiment. In some embodiments, the sensing region 120 extends from a surface of the sensor 100 in one or more directions into space. In various embodiments, input surfaces may be provided by surfaces of casings within which sensor elements reside, by face sheets applied over the sensor elements or any casings, etc. In some embodiments, the sensing region 120 has a rectangular shape (or other shapes) when projected onto an input surface of the input device 100.

The sensor 100 may utilize any combination of sensor components and sensing technologies to detect user input in the sensing region 120. The sensor 100 comprises one or more detector elements (or “sensing elements”) for detecting user input. Some implementations utilize arrays or other regular or irregular patterns of sensing elements to detect the input object 140.

In the optical implementations of the input device 100 set forth herein, one or more detector elements (also referred to as optical sensing elements) detect light from the sensing region. In various embodiments, the detected light may be reflected from input objects in the sensing region, emitted by input objects in the sensing region, or some combination thereof. Example optical detector elements include photodiodes, CMOS arrays, CCD arrays, and other types of photosensors configured to detect light in the visible or invisible spectrum (such as infrared or ultraviolet light). The photosensors may be thin film photodetectors, such as thin film transistors (TFTs) or thin film diodes.

Some optical implementations provide illumination to the sensing region. Reflections from the sensing region in the illumination wavelength(s) are detected to determine input information corresponding to the input object.

Some optical implementations rely on principles of direct illumination of the input object, which may or may not be in contact with an input surface of the sensing region depending on the configuration. One or more light sources and/or light guiding structures may be used to direct light to the sensing region. When an input object is present, this light is reflected from surfaces of the input object, which reflections can be detected by the optical sensing elements and used to determine information about the input object.

Some optical implementations rely on principles of internal reflection to detect input objects in contact with the input surface of the sensing region. One or more light sources may be used to direct light in a transmitting medium at an angle at which it is internally reflected at the input surface of the sensing region, due to different refractive indices at opposing sides of the boundary defined by the sensing surface. Contact of the input surface by the input object causes the refractive index to change across this boundary, which alters the internal reflection characteristics at the input surface. Higher contrast signals can often be achieved if principles of frustrated total internal reflection (FTIR) are used to detect the input object. In such embodiments, the light may be directed to the input surface at an angle of incidence at which it is totally internally reflected, except where the input object is in contact with the input surface and causes the light to partially transmit across this interface. An example of this is presence of a finger introduced to an input surface defined by a glass to air interface. The higher refractive index of human skin compared to air causes light incident at the input surface at the critical angle of the interface to air to be partially transmitted through the finger, where it would otherwise be totally internally reflected at the glass to air interface. This optical response can be detected by the system and used to determine spatial information. In some embodiments, this can be used to image small scale fingerprint features, where the internal reflectivity of the incident light differs depending on whether a ridge or valley is in contact with that portion of the input surface.

Sensors other than optical sensors may also be used. For example, in some embodiments, the sensor 100 is an acoustic sensor, such as an ultrasound sensor having ultrasound sensing elements.

Some implementations are configured to provide images that span one, two, three, or higher dimensional spaces. The input device may have a sensor resolution that varies from embodiment to embodiment depending on factors such as the particular sensing technology involved and/or the scale of information of interest. For example, some biometric sensing implementations may be configured to detect physiological features of the input object (such as fingerprint ridge features of a finger, or blood vessel patterns of an eye), which may utilize higher sensor resolutions and present different technical considerations from some proximity sensor implementations that are configured to detect a position of the input object with respect to the sensing region (such as a touch position of a finger with respect to an input surface). In some embodiments, the sensor resolution is determined by the physical arrangement of an array of sensing elements, where smaller sensing elements and/or a smaller pitch can be used to define a higher sensor resolution.

In some embodiments, the sensor 100 is implemented as a fingerprint sensor having a sensor resolution high enough to capture features of a fingerprint. In some implementations, the fingerprint sensor has a resolution sufficient to capture minutia (including ridge endings and bifurcations), orientation fields (sometimes referred to as “ridge flows”), and/or ridge skeletons. These are sometimes referred to as level 1 and level 2 features, and in an exemplary embodiment, a resolution of at least 250 pixels per inch (ppi) is capable of reliably capturing these features. In some implementations, the fingerprint sensor has a resolution sufficient to capture higher level features, such as sweat pores or edge contours (i.e., shapes of the edges of individual ridges). These are sometimes referred to as level 3 features, and in an exemplary embodiment, a resolution of at least 750 pixels per inch (ppi) is capable of reliably capturing these higher level features.

In some embodiments, the fingerprint sensor is implemented as a placement sensor (also “area” sensor or “static” sensor) or a swipe sensor (also “slide” sensor or “sweep” sensor). In a placement sensor implementation, the sensor is configured to capture a fingerprint input as the user's finger is held stationary over the sensing region. Typically, the placement sensor includes a two dimensional array of sensing elements capable of capturing a desired area of the fingerprint in a single frame. In a swipe sensor implementation, the sensor is configured to capture a fingerprint input based on relative movement between the user's finger and the sensing region. Typically, the swipe sensor includes a linear array or a thin two-dimensional array of sensing elements configured to capture multiple frames as the user's finger is swiped over the sensing region. The multiple frames may then be reconstructed to form an image of the fingerprint corresponding to the fingerprint input. In some implementations, the sensor is configured to capture both placement and swipe inputs.

In some embodiments, the fingerprint sensor is configured to capture less than a full area of a user's fingerprint in a single user input (referred to herein as a “partial” fingerprint sensor). Typically, the resulting partial area of the fingerprint captured by the partial fingerprint sensor is sufficient for the system to perform fingerprint matching from a single user input of the fingerprint (e.g., a single finger placement or a single finger swipe). Some example imaging areas for partial placement sensors include an imaging area of 100 mm² or less. In another exemplary embodiment, a partial placement sensor has an imaging area in the range of 20-50 mm². In some implementations, the partial fingerprint sensor has an input surface that is the same size as the imaging area.

While the input device is generally described in the context of a fingerprint sensor in FIG. 1, embodiments include other biometric sensor devices. In various embodiments, a biometric sensor device may be configured to capture physiological biometric characteristics of a user. Some example physiological biometric characteristics include fingerprint patterns, vascular patterns (sometimes known as “vein patterns”), palm prints, and hand geometry.

In FIG. 1, a processing system 110 is shown in communication with the input device 100. The processing system 110 comprises parts of or all of one or more integrated circuits (ICs) including microprocessors, microcontrollers and the like and/or other circuitry components. In some embodiments, the processing system may be configured to operate hardware of the input device to capture input data, and/or implement a biometric process or other process based on input data captured by the sensor 100.

In some implementations, the processing system 110 is configured to operate sensor hardware of the sensor 100 to detect input in the sensing region 120. In some implementations, the processing system comprises driver circuitry configured to drive signals with sensing hardware of the input device and/or receiver circuitry configured to receive signals with the sensing hardware. For example, a processing system for an optical sensor device may comprise driver circuitry configured to drive illumination signals to one or more LEDs, an LCD backlight or other light sources, and/or receiver circuitry configured to receive signals with optical receiving elements.

In some embodiments, the processing system 110 comprises electronically-readable instructions, such as firmware code, software code, and/or the like. In some embodiments, the processing system 110 includes memory for storing electronically-readable instructions and/or other data, such as reference templates for biometric recognition. The processing system 110 can be implemented as a physical part of the sensor 100, or can be physically separate from the sensor 100. The processing system 110 may communicate with parts of the sensor 100 using buses, networks, and/or other wired or wireless interconnections. In some embodiments, components composing the processing system 110 are located together, such as near sensing element(s) of the sensor 100. In other embodiments, components of processing system 110 are physically separate with one or more components close to sensing element(s) of sensor 100, and one or more components elsewhere. For example, the sensor 100 may be a peripheral coupled to a computing device, and the processing system 110 may comprise software configured to run on a central processing unit of the computing device and one or more ICs (perhaps with associated firmware) separate from the central processing unit. As another example, the sensor 100 may be physically integrated in a mobile device, and the processing system 110 may comprise circuits and/or firmware that are part of a central processing unit or other main processor of the mobile device. In some embodiments, the processing system 110 is dedicated to implementing the sensor 100. In other embodiments, the processing system 110 performs functions associated with the sensor and also performs other functions, such as operating display screens, driving haptic actuators, running an operating system (OS) for the electronic system, etc.

The processing system 110 may be implemented as a set of modules (hardware or software) that handle different functions of the processing system 110. Each module may comprise circuitry that is a part of the processing system 110, firmware, software, or a combination thereof. In various embodiments, different combinations of modules may be used. Example modules include hardware operation modules for operating hardware such as sensor electrodes and display screens, data processing modules for processing data such as sensor signals and positional information, and reporting modules for reporting information. Further example modules include sensor operation modules configured to operate sensing element(s) to detect input, identification modules configured to identify gestures such as mode changing gestures, and mode changing modules for changing operation modes. In one or more embodiments, a first and second module may be comprised in separate integrated circuits. For example, a first module may be comprised at least partially within a first integrated circuit and a separate module may be comprised at least partially within a second integrated circuit. Further, portions of a single module may span multiple integrated circuits.

In some embodiments, the processing system 110 responds to user input (or lack of user input) in the sensing region 120 directly by causing one or more actions. Example actions include unlocking a device or otherwise changing operation modes, as well as GUI actions such as cursor movement, selection, menu navigation, and other functions. In some embodiments, the processing system 110 provides information about the input (or lack of input) to some part of the electronic system (e.g., to a central processing system of the electronic system that is separate from the processing system 110, if such a separate central processing system exists). In some embodiments, some part of the electronic system processes information received from the processing system 110 to act on user input, such as to facilitate a full range of actions, including mode changing actions and GUI actions.

For example, in some embodiments, the processing system 110 operates the sensing element(s) of the sensor 100 to produce electrical signals indicative of input (or lack of input) in the sensing region 120. The processing system 110 may perform any appropriate amount of processing on the electrical signals in producing the information provided to the electronic system. For example, the processing system 110 may digitize analog electrical signals obtained from the sensor electrodes. As another example, the processing system 110 may perform filtering or other signal conditioning. As yet another example, the processing system 110 may subtract or otherwise account for a baseline, such that the information reflects a difference between the electrical signals and the baseline. As yet further examples, the processing system 110 may determine positional information, recognize inputs as commands, authenticate a user, and the like.

In some embodiments, the sensing region 120 of the sensor 100 overlaps at least part of an active area of a display screen, such as embodiments where the sensor 100 comprises a touch screen interface and/or biometric sensing embodiments configured to detect biometric input data over the active display area. For example, the sensor 100 may comprise substantially transparent sensor electrodes. The display screen may be any type of dynamic display capable of displaying a visual interface to a user, and may include any type of light emitting diode (LED), organic LED (OLED), cathode ray tube (CRT), liquid crystal display (LCD), plasma, electroluminescence (EL), or other display technology. The display screen may be flexible or rigid, and may be flat, curved, or have other geometries. In some embodiments, the display screen includes a glass or plastic substrate for TFT circuitry and/or other circuitry, which may be used to provide visuals and/or other functionality. In some embodiments, the display device includes a cover lens (sometimes referred to as a “cover glass”) disposed above the display circuitry. The cover lens may also provide an input surface for the input device. Example cover lens materials include plastic, optically clear amorphous solids, such as chemically hardened glass, and optically clear crystalline structures, such as sapphire. In accordance with the disclosure, the sensor 100 and the display screen may share physical elements. For example, some embodiments may utilize some of the same electrical components for displaying visuals and for input sensing. In one embodiment, one or more display electrodes of a display device may be configured for both display updating and input sensing. As another example, the display screen may be operated in part or in total by the processing system 110 in communication with the input device.

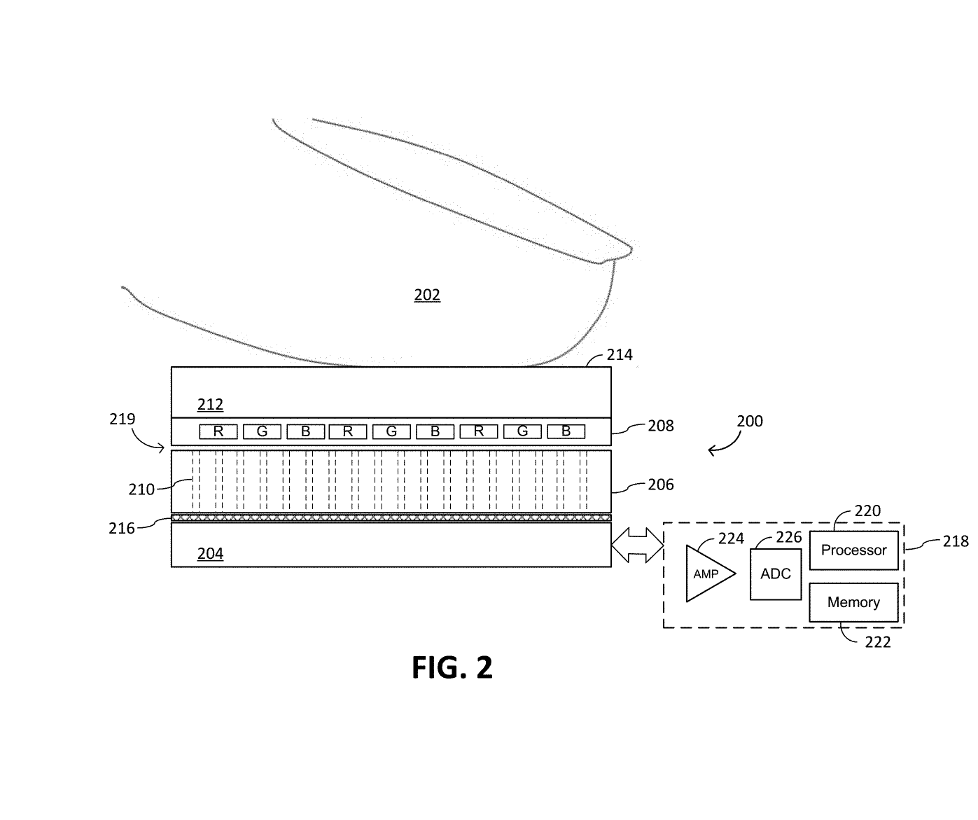

FIG. 2 illustrates a stack up of an example of an under display imaging device 200 used to image an input object 202, such as a fingerprint, other biometric or object. The imaging device 200 includes a sensor or image sensor 204 and, in some embodiments, a filter (or a filter layer) 206. A cover layer 212 may be disposed over the imaging device 200 and configured to protect the inner components of the imaging device 200 such as the sensor 204 and the filter 206. The cover layer 212 may include a cover glass or cover lens. A display 208 is disposed below cover layer 212. The display 208 may be an OLED display illustratively depicted as having Red (R), Green (G) and Blue (B) pixels—although the display 208 may include pixels of any color. Other display stacks such as microLED, inorganic displays, or other emissive displays can be used as previously described. The imaging device 200 may be used to image an input object 202 over any part of an overall display 208, over designated portions of the display 208, or over a cover lens or cover glass without a display. It will be understood that the imaging device 200 as well as each of the layers is shown in simplified form. The imaging device 200 may include other layers, layers may be eliminated or combined, and the various layers may include components and sub-layers that are not shown. For example, the display 208 may include sub-layers such as a substrate, pixel layer, and cover layer (e.g., up-glass).

A sensing region for the input object 202 is defined above the cover layer 212. The sensing region includes sensing surface 214 formed by a top surface of the cover layer 212, which provides a contact area for the input object 202 (e.g., fingerprint or more generally, other biometric or object). As previously described above, the sensing region may extend above the sensing surface 214. Thus, the input object 202 need not contact the sensing surface 214 to be imaged.

Although generally described in the context of fingerprint for illustrative purposes, the input object 202 can be any object to be imaged. Input object 202 may have various features. For example, in the case of a fingerprint, the input object 202 has ridges and valleys which may be optically imaged. Illumination of the input object 202 for imaging may be provided by display components, e.g., OLEDs and/or by a separate light source (not shown) which may be mounted under or above the filter 206. When the light source is mounted below the filter 206, portions of the filter 206 may be transparent to allow light to reach cover layer 212 and sensing surface 214.

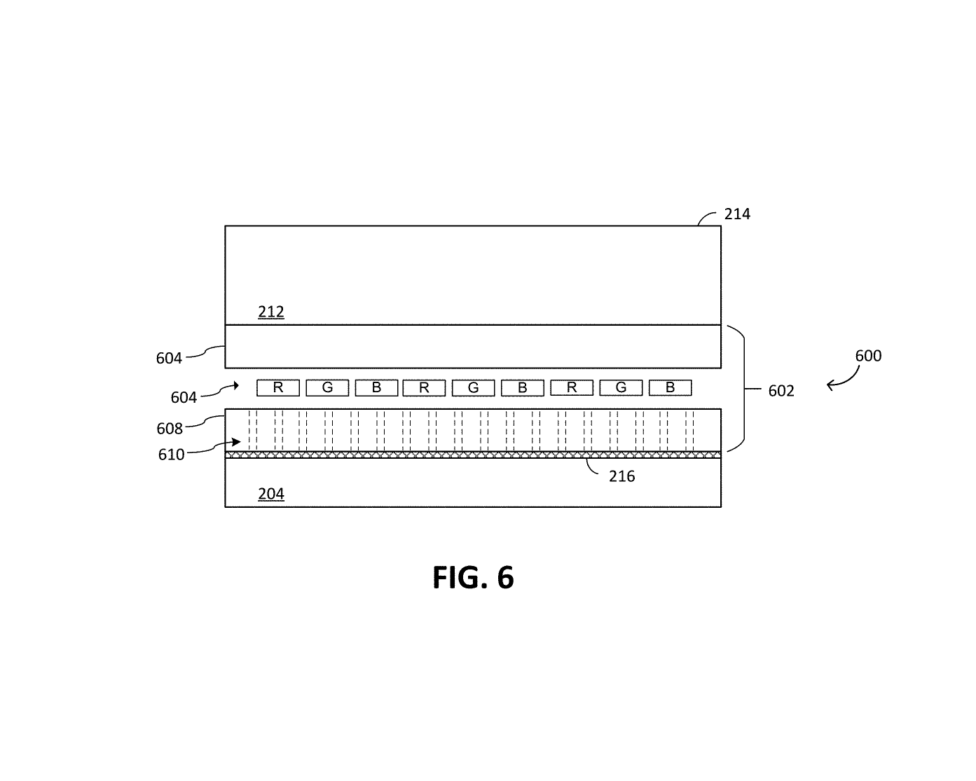

For embodiments where imaging device 200 is configured for optical imaging, filter 206 may be configured to condition light reflected from the input object 202 and/or at the sensing surface 214. Optional filter 206 may be a collimator or any suitable type of filter. When deployed as a collimator, the filter 206 includes an array of apertures, or holes, 210 with each aperture 210 being generally above one or more optical sensing elements of the sensor 204 such that light passing through the apertures 210 reaches the sensing elements. The array of apertures 210 may form a regular or irregular pattern. The apertures 210 may be voids or may be made of transparent material (e.g., glass), or a combination thereof, and may be formed using additive or subtractive methods (e.g., laser, drilling, etching, punch and the like). In areas other than apertures 210, the filter 206 may include material (e.g., metal) that will block, reflect, absorb or otherwise occlude light. Thus, the filter 206 generally only permits light rays reflected from the input object 202 (e.g., finger) or sensing surface 214 at normal or near normal incidence (relative to a longitudinal plane defined by a longitudinal axis of the filter 206) to pass and reach the optical sensing elements of the sensor 204. It should be understood that the collimator can be manufactured using any suitable methods or materials, and further, that the collimator or portions thereof can additionally or alternatively permit non-normal light rays to reach the sensor (e.g., with an angled or tilted angle of acceptance). As described in connection with FIG. 6, the filter 206 may be embedded within a substrate of the display 208.

In some embodiments, the sensor 204 is disposed below the filter 206. In optical sensing embodiments, the sensor 204 includes an array of optical sensing elements, with one or more sensing elements in the optical sensor array being disposed generally below an aperture 210 of the filter 206 when filter 206 is employed. Optical sensing elements detect the intensity of light passing through the filter 206 and which becomes incident on one or more of the sensing elements. Examples of optical sensors include a TFT-based sensor formed on a non-conductive substrate, such as glass, or a CMOS image sensor which may be formed from a semiconductor die, such as a CMOS Image Sensor (CIS) Die. In other embodiments, alternative sensing technologies using different types of sensing elements may be used. For example, the sensor 204 may include an acoustic sensor such as an ultrasonic sensor that includes an array of acoustical sensing elements.

A control circuit 218 is communicatively coupled, e.g., electrically and logically connected, to the sensor 204. The control circuit 218 may be configured to control operation of the sensor 204. For example, control circuit 218 may read values from sensing elements of sensor 204 as part of a biometric imaging process. The control circuit 218 may include a processor 220, memory 222 and/or discrete components. The processor may include circuitry 224 to amplify signals from the sensor 204, an analog-to-digital converter (ADC) 226 and the like. The control circuit 218 may be separate, as generally shown, or may be partially or entirely integrated with the sensor 204.

In certain embodiments, gaps (e.g., air gaps) may exist between one or more layers of the imaging device 200. For example, in the example shown, a gap 219 is present between the filter 206 and the display 208. Such gaps may exist between other layers and, conversely, the various layers of the imaging device 200 may lack gaps.

As will be appreciated, components of the imaging device 200 may generate noise. For example, signaling within the display 208 may generate electrical noise and fluctuations of emitted light from the display may generate light noise. Electrical noise and light noise may, in turn, couple to the sensor 204 and, thus, may interfere with imaging of the input object 202. As will further be appreciated, the amount of noise coupled to the sensor 204 may depend on a variety of factors, including, for example, the distance between the display 208 and the sensor 204, the absence or presence and magnitude of any air gaps, and/or material properties and thickness of intervening layers.

To mitigate the effects of noise, some embodiments provide a shield layer or noise shield 216. In certain embodiments, the shield layer 216 may include optically opaque portions, e.g., metal. In other embodiments, the shield layer 216 may include transparent portions, such as an indium tin oxide (ITO), for example, where sensing elements underneath the shield are optical sensors used in optical imaging of the input object 202. In other embodiments, the shield layer 216 includes a combination of transparent and opaque materials. Thus, the shield layer 216 may include multiple layers.

The shield layer 216 m disposed between circuitry of the display 208 and the sensing elements of the sensor 204. The location of the shield layer 216 may vary, for example, the shield layer 216 may form a discrete layer between the display 208 and the sensor 204. Alternatively, the shield layer 216 may be above the sensing elements, but formed as an integral part of the sensor 204. As another alternative, the shield layer 216 may be below display pixels of the display 208, but either as an integral portion of a bottom display 208 or affixed to the bottom of the display 208. As yet another alternative, the shield layer 216 may be incorporated within the filter layer 206.

Various types of noise that may affect the sensor 204 may be represented by mathematical relationship:

Nₒ=\sqrt{N²−Nₑ²−Nₛ²}

Where:

Nₑ=Electric Noise, e.g., electric noise intrinsic to the sensor such as noise generated by analog front end readout and from sensor pixels.

Nₛ=Shot Noise

Nₒ=Other Noise

N=Total Noise

Typically, electric noise (Nₑ) is measured in a dark environment and shot noise (Nₛ) is calculated from the image mean.

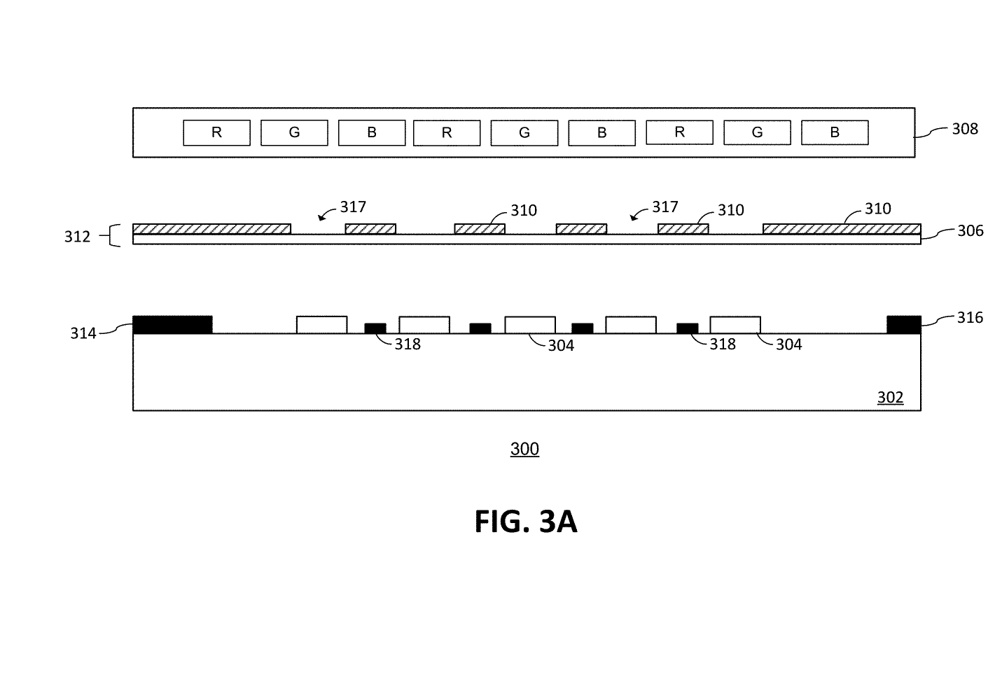

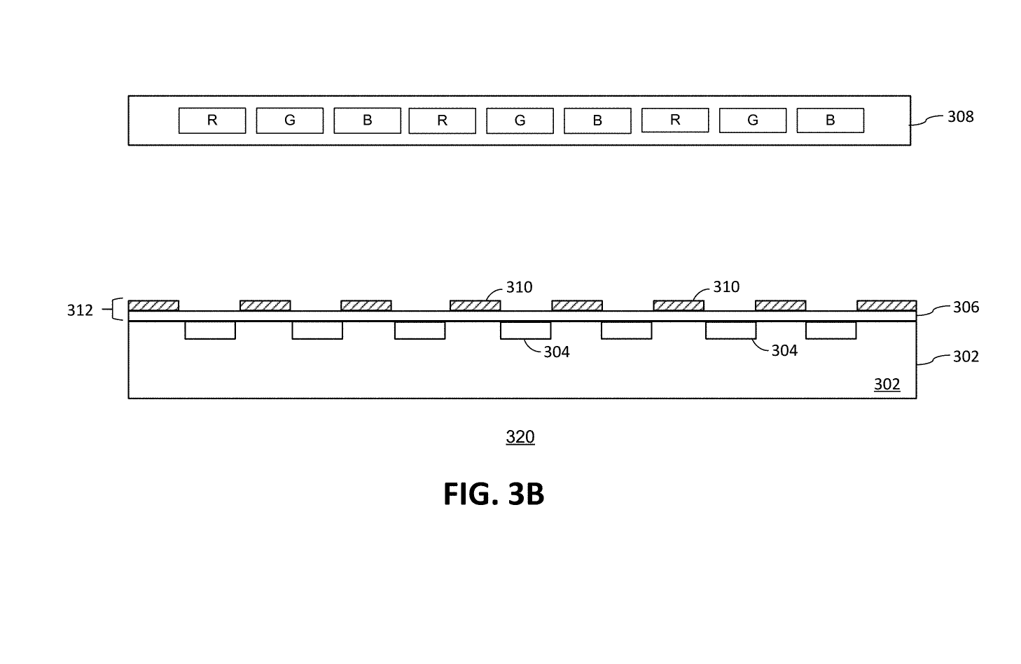

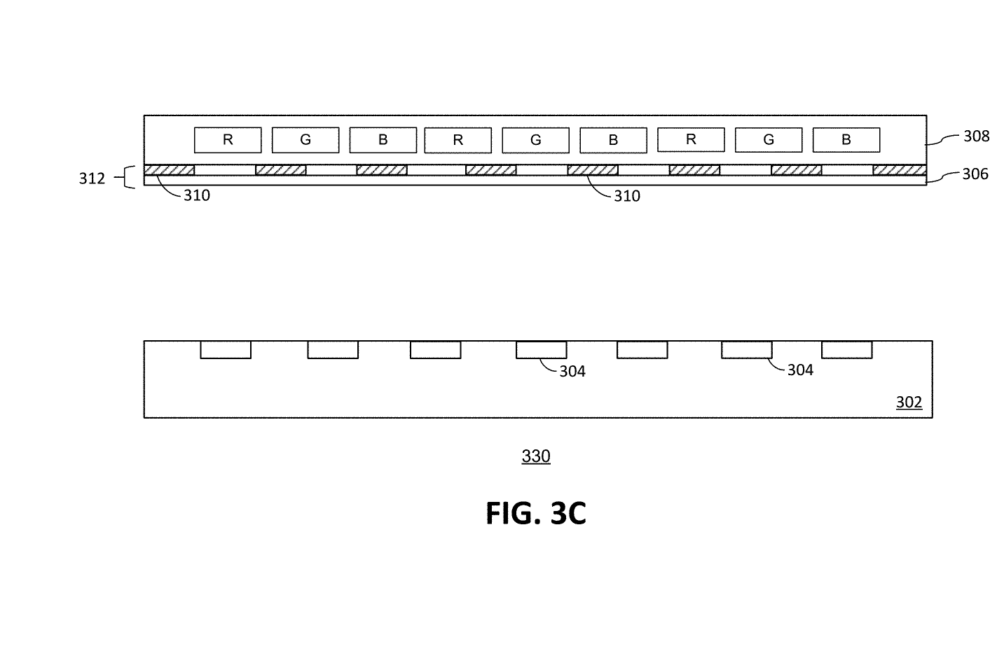

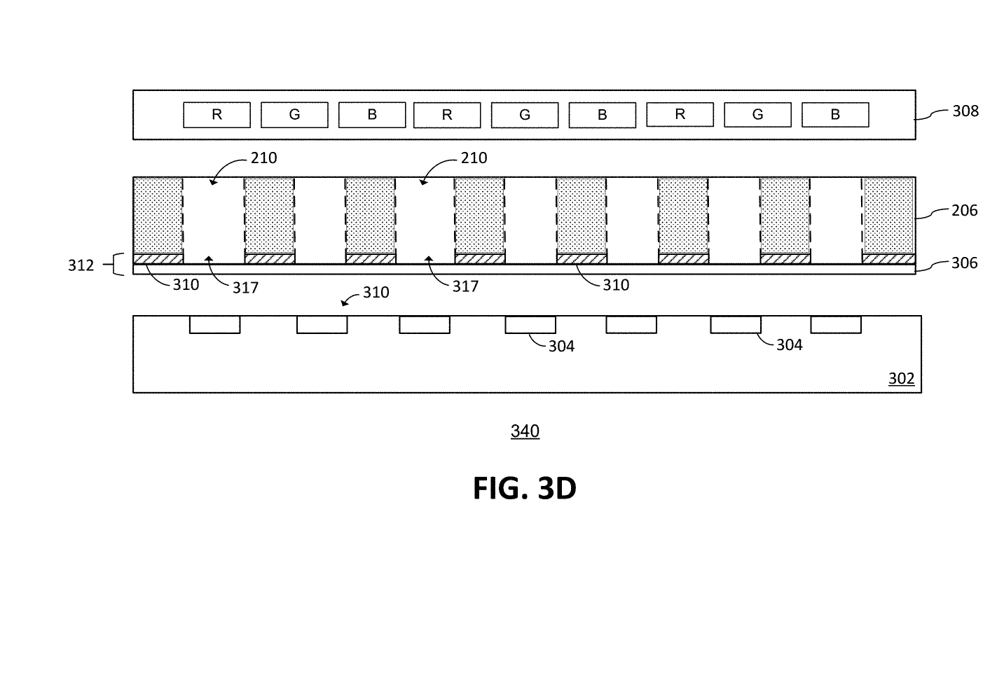

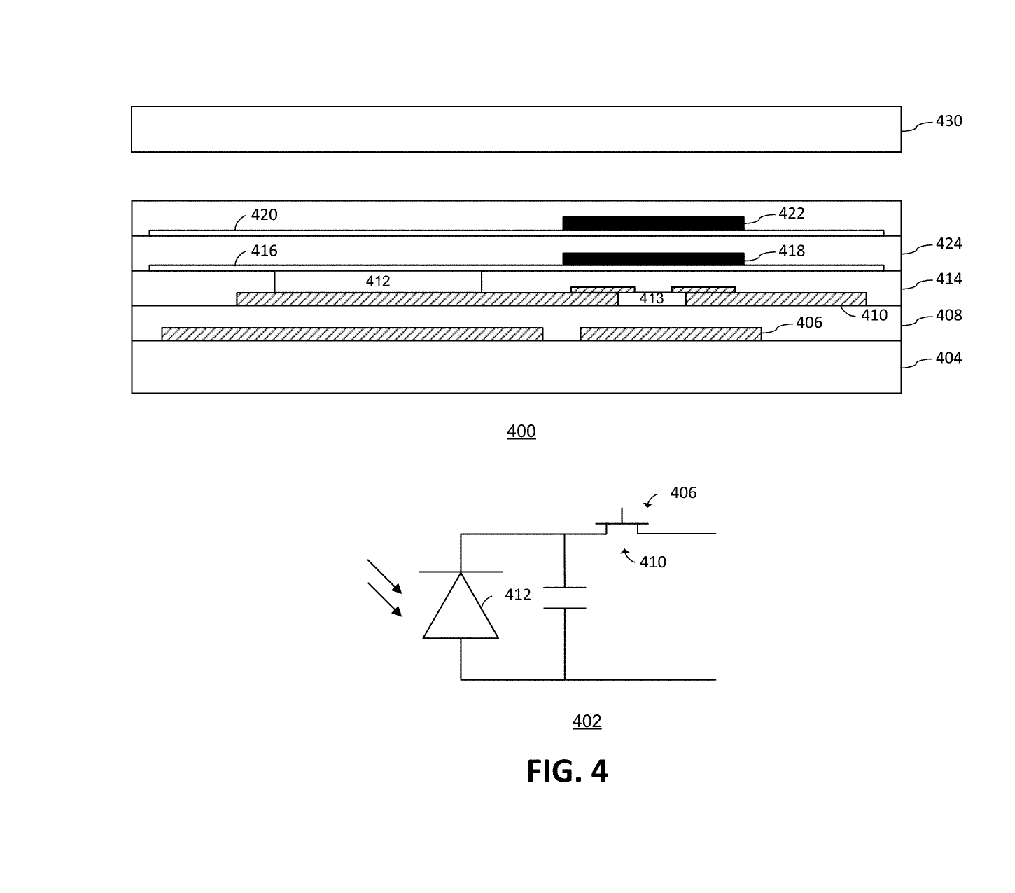

Potential sources of other noise (Nₒ) include electrical noise from a display, such as an OLED display coupled to the imager and light noise, which results from the changes in light intensity emitted from the display over time. FIGS. 3A-4 illustrate examples of embodiments for minimizing the amount of electrical noise from, for example, the display.

FIG. 3A illustrates a cross sectional view of an arrangement 300 according to one embodiment. As shown, the arrangement includes a sensor 302 disposed below a display 308. The display 308 may be of any suitable type, such an OLED display, as generally described in connection with the display 208 of FIG. 2.

The sensor 302 may also be of any suitable type, for example, an optical TFT-based sensor, optical CMOS image sensor, and ultrasound sensor. The sensor 302 may include an array of sensing elements 304 formed in a regular or irregular pattern. The sensor 302 may include additional components. For example, in arrangements employing an array of sensing elements, such as optical or acoustic sensing elements, the sensor 302 may include a driver 314 and readout circuit 316 for controlling readout of the various sensing elements 304 in the array, e.g., by activating TFT switches 318.

The arrangement 300 further includes a noise shield 312 that include a first shield layer 306 and a second shield layer 310. As shown, the noise shield 312 is disposed between display 308 and the sensing elements 304 of the sensor 302.

The first shield layer 306, also called a first conductive portion, covers all, or substantially all, of the sensor 302. In arrangements relying on optical imaging, and hence optical sensing, the first shield layer 306 is transparent. For example, the first shield layer 306 is an Indium Tin Oxide (ITO) layer. Because ITO is transparent, the construction allows for the transmission of light through the first shield layer 306 and, thus, allows light to reach sensing elements 304 as part of the biometric imaging process. At the same time, ITO is conductive thereby allowing layer 306 to act as a noise shield. Thus, as generally shown, the first shield layer 306 may cover (e.g., disposed directly above) the sensing elements 304 without adversely impacting imaging. Examples of other suitable transparent conductive materials include Poly (3,4-ethylenedioxythiophene) (PEDOT), Indium Zinc Oxide (IZO), Aluminum Zinc Oxide (AZO), other transparent conductive oxides, and the like.

In non-optical sensing arrangements, such as where acoustic sensing is used, the first shield layer 306 may similarly be constructed of material, such as ITO. Alternatively, the first shield layer 306 may be constructed of a conductive non-transparent material, such as Copper (Cu), Aluminum (Al), Silver (Au), Gold (Ag), Chromium (Cr), Molybdenum (Mo), metal alloys and the like as transmission of light is not necessary.

To further mitigate noise, the first shield layer 306 may be electrically connected to a fixed voltage, for example, ground.

Second shield layer 310, also called a second conductive portion, may be optional. The second shield layer 310 may be selectively disposed above the first shield layer 306. In optical arrangements, the second shield layer 310 may cover portions of the sensor 302, such that the second shield layer 310 does not cover (excludes) portions or areas of the sensor 302 that are directly or generally above the individual sensing elements 304. For example, gaps or openings 317 may be formed in second shield layer 310, above sensing elements 304. In some embodiments, the second shield layer 310 may extend over portion(s) of the area above the sensing elements 304, e.g., there may be some overlap between the second shield layer 310 and the area directly above the sensing elements 304. Thus, the second shield layer 310 may be made of non-transparent material, such as metal, when the sensing elements 304 are optical sensing elements. When the sensing elements 304 are non-optical sensing elements, such as acoustic sensing elements, the second shield layer 310 (if used) may be a continuous layer that covers all or substantially all of the sensor 302.

It will be appreciated that the second shield layer 310 may further improve noise reduction provided by the first shield layer 306. Thus, the second shield layer 310 may be disposed above electrical components susceptible to noise. For example, second shield layer 310 is above driver circuit 314, readout circuitry 316, and other electrical components such as TFT switches 318.

The second shield layer 310 is electrically connected or coupled to the first shield layer 306. The electrical connection of the first shield layer 306 and the second shield layer 310 decreases the collective resistance of first shield layer 306 and second shield layer 310 thereby enhancing the ability of the shield layers to mitigate electrical noise coupled to the sensor 302, particularly high frequency noise.

FIG. 3B illustrates an alternative arrangement 320. Similar to the arrangement 300 of FIG. 3A, noise shield 312 is disposed between the display 308 and sensing elements 304. However, in the arrangement 320, the noise shield 312 forms a part of the sensor 302 or, alternatively, is affixed directly above the sensor 302. It will be noted that, although the noise shield 312 forms part of the sensor 302, or is affixed to the top of the sensor 302, the noise shield 312 is located above the sensing elements 304 and, therefore, will provide shielding to the sensing elements 304 and any corresponding circuitry (not shown). As with FIG. 3A, the noise shield 312 may comprise multiple layers. For example, where the sensing elements 304 are optical sensing elements, the first shield layer 306 maybe transparent thereby allowing the transmission of light. The second shield layer 310 may be non-transparent, e.g., metal, which provides enhanced noise shielding over areas not requiring transmission of light. A specific example of integration of the noise shield 312 with the sensor 302 is further described in connection with FIG. 4.

FIG. 3C illustrates yet another arrangement 330. Similar to FIG. 3A-3B, the noise shield 312 is above the sensor elements 304. However, in the embodiment 330, the noise shield 312 is integrated with the display 308. Integration may be achieved by, for example, disposing the first shield layer 306 and second shield layer 310 on a lower level of the display stack. For example, the noise shield 312 may form layers below a layer containing individual display pixels or elements (e.g., RGB display pixels) and their associated circuitry, e.g., circuitry used to drive individual pixels or elements. As an alternative, the noise shield 312 may be affixed directly below the display 308.

FIG. 3D illustrates yet another arrangement 340. Filter 206 (FIG. 2) is interposed between the sensor 302 and the display 308. As previously described, the filter 206 may, for example, be a collimator, with an array or other arrangement of apertures 210, which permit the transmission of light. In the arrangement of FIG. 3D, the noise shield 312 is formed integral with or affixed to the filter 206. Because the first shield layer 306 is transparent, it may cover the entire area of the filter 206. The second shield layer 310 is formed such that it does not cover the apertures 210 thereby allowing light traversing the filter apertures 210 to reach the sensing elements 304. Thus, gaps 317 are present in the second shield layer 310. Although shown at the bottom of the filter 206, the noise filter 312 may be disposed at any layer within the filter 206, e.g., middle or top. The size of the apertures 210 need not match the size of the gaps 317.

FIG. 4 illustrates a cross sectional view of a TFT optical sensor 400 and a schematic representation of a sensing element 402. As shown in FIG. 4, sensing element 402 includes a TFT with a photodiode, e.g., PIN diode. Also shown in FIG. 4, the optical TFT sensor 400 is configured to be mounted below a display 430.

The TFT optical sensor 400 includes a non-conducting substrate 404. The non-conductive substrate 404 may, for example, be glass. Above the substrate 404 is a metallization layer, e.g., gate metal 406, followed by a first passivation, or insulating layer 408. Above the first passivation layer 408 is another metallization layer 410 (e.g., source, drain and a-Si 413), followed by a light sensing photodiode, e.g., PIN diode, 412. The PIN diode 412 may be formed in passivation layer 414.

A bias electrode 416 VCOM is disposed above passivation layer 414 and PIN diode 412. The bias electrode 416, also called a transparent bias electrode, may be formed by ITO or other suitable transparent conductive materials such as those described in connection with FIG. 3. It is noted that the bias electrode 416 may carry a DC signal.

Above the bias electrode 416 is a light shield 418, which may, for example, be constructed of metal. The light shield 418 protects, for example, the TFT switch from light which may cause noise in the signal from the PIN diode. Inclusion of the light shield 418 is optional and may, for example, be eliminated in view of the noise shield metal (second noise shield layer 422) described below. In order to permit light to reach the PIN 412 as part of the imaging and light sensing process, the light shield 418 may not cover the entirety of the sensing element. For example, the light shield 418 is not disposed in the area above the PIN 412.

In accordance with certain embodiments, a first noise shield layer 420 is disposed above passivation layer 424. In the example, the first noise shield layer 420 covers the entire sensor (or substantially all of sensor) including the portion or area above the light sensing PIN 412. The first noise shield layer 420 is transparent and conductive and may be made of, for example, ITO or other suitable transparent conductive materials such as those described in connection with FIG. 3A. To facilitate mitigation of noise, the first noise shield layer 420 is connected to a constant voltage, for example, ground.

A second noise shield layer 422 is optionally disposed above, and electrically connected (e.g., shorted or coupled to) the first noise shield layer 420. As shown, the second noise shield layer 422 is selectively positioned to cover portions susceptible to noise, such as the TFT switch, but does not to cover portions or areas above the PIN 412. The second noise shield layer 422 may be non-transparent (opaque) and thus may be constructed of metal, for example, as described in connection with FIG. 3A. In certain embodiments, the second noise shield layer 422 may block light sufficiently such that a need for light shield 418 is obviated. A relatively high conductivity of noise shield layer 422 decreases the resistance of the combined first and second noise shield layers, which increases the noise mitigation provided by the overall sensor design particularly with respect to high frequency noise.

FIG. 4 illustrates a single sensing element. It will be appreciated that a sensor will typically include many sensing elements, e.g., an array of sensing elements such as generally described in connection with FIG. 3. The first shield layer will generally cover the entire array and the second shield layer may only cover portions of the array, e.g., portions that are not directly above the sensing elements.

It will further be appreciated that the specific example shown and described with reference to FIG. 4 is an example of an optical TFT sensor stack-up. The actual layers may vary. The example is illustrative of how first and optionally second noise shield layers may be interposed between an optical sensor element and the display. Of course, it will be appreciated that the noise shield layers may be used with other optical and non-optical sensing elements such as generally described in connection with FIGS. 3A-3D.

The noise mitigation described minimizes the impact of wideband and narrowband noise that may be present in under display biometric sensing arrangements.

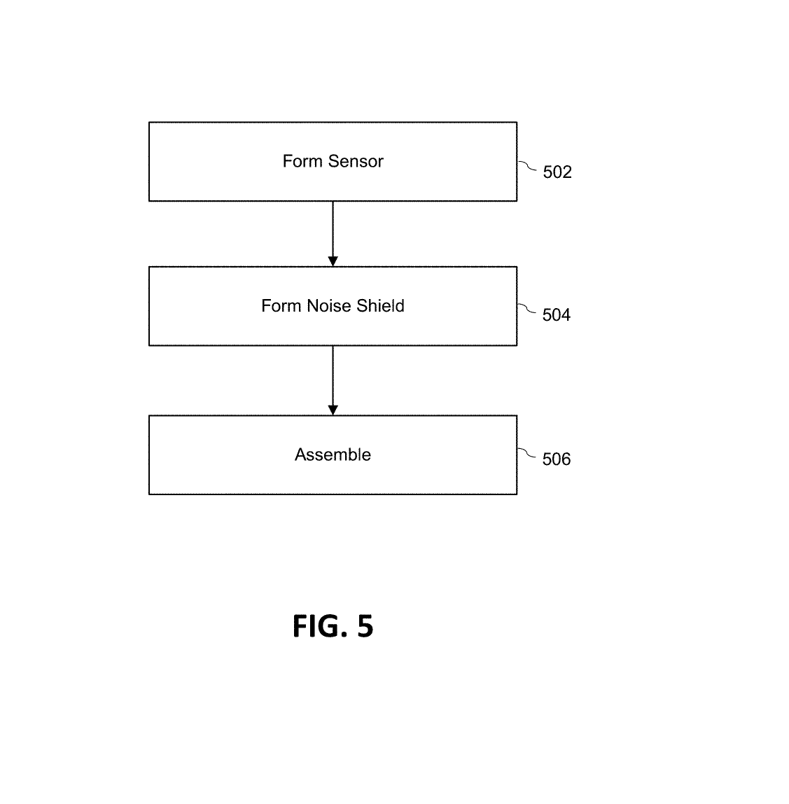

FIG. 5 illustrates a method a making a sensor arrangement having a noise shield according to certain embodiments. As will be appreciated, the steps shown are by way of example and need not be performed in the order shown unless otherwise apparent. For example, the order of forming the noise shield and sensor may be reversed. In addition, steps may be added or eliminated. For example, the sensor and noise shield need not be mounted under a display.

In step 502, the sensor is formed. Typically, the sensor will include an array of sensing elements and a substrate. Suitable sensing elements include sensing elements 304 as described in connection with FIGS. 3A-3D. The substrate may be of any suitable type for the sensor elements 304. For example, in the case of TFT-based/photodiode sensing elements, the sensing elements may be formed on a non-conductive substrate such as glass. In the case of a CMOS based sensor, the sensing elements may be formed on a semiconductor die, such as a CMOS Image Sensor (CIS) Die. Other components, such as driver and readout circuitry may also be formed on, or integral with, the substrate.

In step 504, the noise shield is formed. As generally described, the noise shield may include a first continuous layer, called a first shield layer, which is formed of conductive material. Depending on the sensing technology used, the first shield layer may be a transparent material. The first shield layer may be sized to cover the entirety of the sensor. A second optional shield layer may be formed. The second shield layer may include gaps or openings to allow light to reach the sensing elements. The first shield layer and second shield layer may be electrically coupled.

In step 506, the sensor and noise shield are assembled with the noise shield disposed above the sensor and the gaps or openings in the second shield layer generally disposed above the sensing elements. The noise shield may or may not be affixed to the sensor as described in connection with FIGS. 3A-3D. A display is then disposed above sensor and noise shield. As previously described in connection with FIG. 3C, the arrangement may be affixed to, or integrated with, the bottom of a display.

FIG. 6 illustrates an example of an under display imaging device 600 that includes at least certain portions integrated within a display, such as an OLED display. The arrangement is similar to the imaging device 200 described in connection with FIG. 2 with like reference numbers referring to like components.

The imaging device 600 includes a sensor or image sensor 204. Also shown is cover layer 212 having a sensing region including sensing surface 214. A display 602, such as an OLED display, is illustratively depicted as having Red (R), Green (G) and Blue (B) pixels—although the display 602 may include pixels of any color. In some embodiments, other display stacks such as microLED or inorganic displays or other emissive displays can be used as previously described. The imaging device 600 may optionally include a noise shield 216 as previously described.

The display 602 includes a substrate 608, a pixel layer 604, and a cover layer 606. The substrate 608 is made of any suitable material, for example, glass. The pixel layer, including for example RGB pixels and associated circuitry are built upon the substrate 608. The cover layer 606 is made of any suitable transparent or semitransparent material, such as glass.

The imaging device 600 also includes a filter 610. The filter 610 is formed within the display substrate 608. Similar to filter 206 (FIG. 2), the filter 610 conditions light reflected from an input object at sensing surface 214 by, for example, only permitting light rays at normal or near normal incidence (relative to the longitudinal axis of the substrate 608) to pass and reach sensing elements of the sensor 204. The angle of light rays which pass and reach the sensing elements is referred to herein as an acceptable angle. For example, the substrate 608 may include an embedded collimator as the filter 610. The collimator 610 may be formed using, for example, a series or array of Fiber Optic Plates (FOPs) formed within the substrate 608. By integrating the filter 610 in the display substrate 608, the thickness of the display stack up is only increased by the thickness of the image sensor assuming the optional noise shield 216 is not employed. Thus, the thickness of the overall display stack up may only be increased by, for example, on the order of 0.05 mm for a film based TFT sensor or 0.3-0.5 mm for a glass TFT sensor. Such an arrangement allows additional room for other device components such as battery capacity. The arrangement also decreases the weight of the device because fewer components are needed for the imaging device.

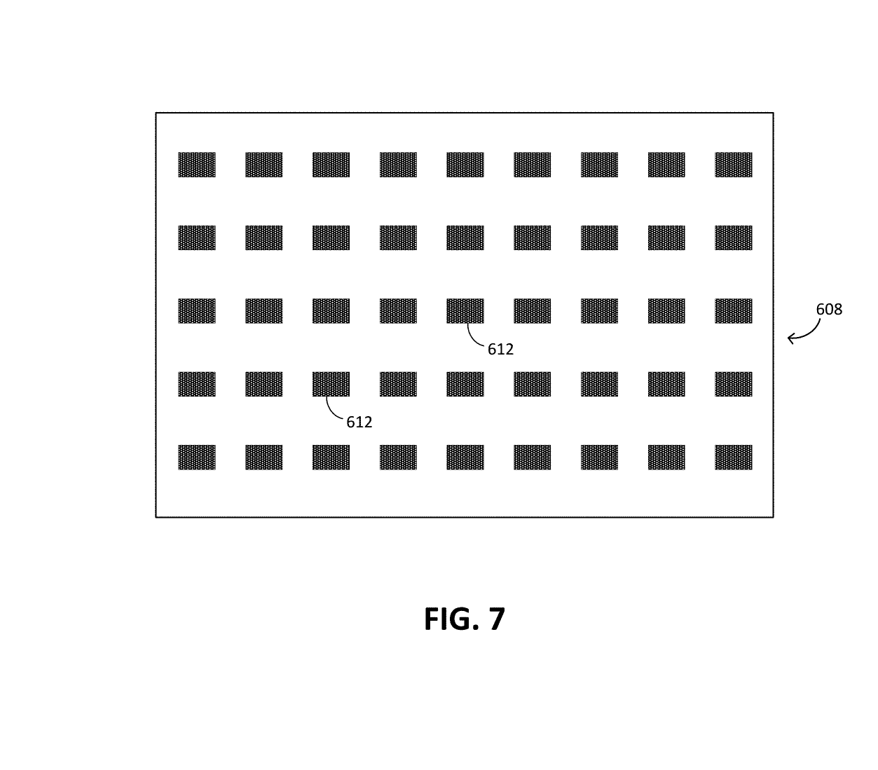

FIG. 7 shows a plan view of the display substrate 608 with integrated filter. As shown, the display substrate 608 includes a series of filter components 612. The filter components 612 may, for example, be constructed of FOPs. The FOPs may be fused (e.g., under heat and/or pressure) to the display substrate 608. The FOPs allow the image (e.g., fingerprint) to be transferred from the sensing surface 214 to the image sensor 204 without degradation in resolution.

The FOPs may be arranged as an array in the display substrate as generally depicted in FIG. 6. However, any suitable regular or irregular pattern of FOPs may be used with each FOP generally disposed above one or more sensing elements. The substrate 608 may be coated with a light absorbing material in areas not occupied by the FOPs.

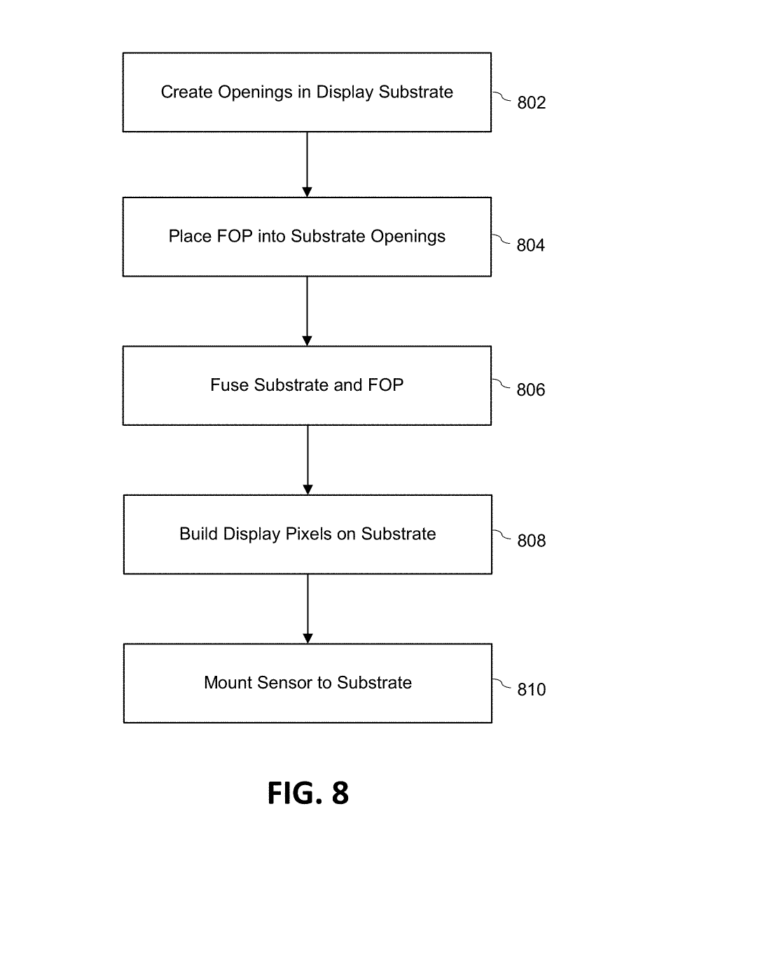

FIG. 8 illustrates a method of making an imaging device with a filter integrated in the display substrate. As with previous methods described herein, the steps need not be carried out in the order shown, and certain steps may be eliminated, except where otherwise apparent from the description.

In step 802, openings are created in the display substrate corresponding to the size and location where the FOPS are to be inserted. The openings may be made using any suitable method, e.g., laser, drilling, etching, punch and the like. In step 804, the FOPs are inserted into the corresponding openings in the display substrate.

In step 806, the FOPs are affixed to the display substrate. This may be done by fusing the FOPs to the display substrate using heat and/or pressure. In step 808, the display pixels and associated circuitry (e.g., driver circuitry) are built on top of the display substrate.

In step 810, the sensor may be mounted to the bottom of the display substrate. However, it will be understood that the sensor need not be physically attached to the display substrate. A noise shield, if used, is interposed between the bottom of the display substrate and sensor. As previously described in connection with FIG. 3C, the noise shield can be attached to or integrated with lower levels of the display stack.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Example embodiments are described herein. Variations of those embodiments will become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. For example, although generally described for use as a biometric sensor, the described arrangement may be used to image any form of an input object. Moreover, any combination of the above-described elements in all possible variations thereof is encompassed by the invention unless otherwise indicated herein or otherwise clearly contradicted by context.

1. An imaging device for imaging an input object, comprising:
an image sensor comprising an array of sensing elements, the image sensor configured to be mounted below a display; and
a noise shield layer disposed above and covering the array of sensing elements.

2. The imaging device of claim 1, wherein the noise shield layer comprises a transparent conductive material.

3. The imaging device of claim 2, wherein the transparent conductive material is indium tin oxide (ITO).

4. The imaging device of claim 1, wherein the image sensor is an optical sensor.

5. The imaging device of claim 4, wherein the optical sensor comprises a thin film transistor (TFT) sensor including a photodiode.

6. The imaging device of claim 1, where in the image sensor is an acoustic sensor.

7. The imaging device of claim 1, wherein the noise shield layer further comprises:
a first conductive layer covering a first area above the sensing elements; and
a second conductive layer covering a second area excluding third areas above the sensing elements, wherein the second conductive layer is electrically connected to the first conductive layer.

8. The imaging device of claim 7, wherein the first conductive layer is transparent and the second conductive layer is opaque.

9. An optical imaging device for imaging an input object, comprising:
an emissive display;
an optical sensor comprising an array of optical sensing elements, the optical sensor being configured to be mounted below a display; and
a noise shield layer disposed above and covering the array of optical sensing elements.

10. The optical imaging device of claim 9, wherein the noise shield layer is affixed to a top of the optical sensor.

11. The optical imaging device of claim 9, wherein the noise shield layer is integral with the optical sensor.

12. The optical imaging device of claim 9, wherein the noise shield layer is affixed to a bottom of the emissive display.

13. The optical imaging device of claim 9, wherein the noise shield layer is integral with the emissive display.

14. The optical imaging device of claim 9, further comprising:
a filter layer disposed between the emissive display and the optical sensor.

15. The optical imaging device of claim 14, wherein the noise shield layer is affixed to the bottom of the filter layer.

16. The optical imaging device of claim 14, wherein the noise shield layer is integral with the filter layer.

17. The optical imaging device of claim 9, further comprising:
a display substrate comprising a light filter configured to only allow light falling within an acceptance angle to pass through the light filter; and
a pixel layer comprising a plurality of display pixels and control circuitry disposed on the display substrate.

18. The optical imaging device of claim 17, wherein the light filter comprises a plurality of fiber optic plates.

19. The optical imaging device of claim 18, wherein the array of optical sensing elements is aligned with the plurality of fiber optic plates.

20. The optical imaging device of claim 19, further comprising a noise shield interposed between the optical sensing elements and the display substrate.

21. An electronic device for imaging an input object, the electronic device including an emissive display comprising:
a first display layer comprising an array of display elements and associated control circuitry; and
a second display layer disposed below the first display layer, the second display layer including a noise shield, the noise shield comprising:
a first conductive layer, wherein the first conductive layer is transparent; and
a second conductive layer electrically connected to the first conductive layer, wherein the second conductive layer is opaque, and wherein the second conductive layer includes an array of gaps allowing light to pass therethrough.

22. The electronic device of claim 21, further comprising:
an optical sensor comprising an array of optical sensing elements, the optical sensor being mounted below the emissive display and being arranged to receive the light passing through the gaps in the second conductive layer of the noise shield.

23. The electronic device of claim 22, wherein the array of optical sensing elements comprises a plurality of thin film transistors and a plurality of photodiodes.

24. The electronic device of claim 21, wherein the first conductive layer is indium tin oxide (ITO) and the second conductive layer is metal.
